(19) United States
(12) Patent Application Publication
(10) Pub. No.: US 2010/0148800 A1
(43) Pub. Date: Jun. 17, 2010

(54) INDUCTIVE SWITCH FOR ADJUSTMENT AND SWITCHING FOR APPLICATIONS IN SPECIAL ENVIRONMENTS

(75) Inventor: Mauro Del Monte, Modena (IT)

Correspondence Address: Modiano & Associati, Via Meravigli 16, Milano, 20123, IT

(73) Assignee: M.D. MICRO DETECTORS S.P.A., MODIANA (IT)

(21) Appl. No.: 12/733,284

(22) PCT Filed: Aug. 28, 2008
(86) PCT No.: PCT/EP2008/061280

§ 371 Date: Feb. 22, 2010

(30) Foreign Application Priority Data
Aug. 31, 2007 (IT) MO2007/A000275

(51) Int. Cl. G01R 27/28

(52) U.S. Cl. 324/655; 116/205

(57) ABSTRACT

An inductive programming switch for applications in special environments, comprising an inductive component and a container in which the inductive component is accommodated proximate to a wall of the container, the inductive component being connected to an electronic evaluation circuit, which is adapted to detect variations of parameters of the inductive component caused by the approach of a metallic object to the wall, the evaluation circuit being adapted to detect and identify a sequence of approach/spacing of the metallic object with respect to the wall and for modifying its functional parameters according to the sequence.

The present invention relates to an inductive switch for adjustment and switching for applications in special environments, particularly for use as a pushbutton in hostile or sterile environments.

### BACKGROUND OF THE INVENTION

Switches are known which are adapted to be used in hostile environments, such as environments in which the electrical parts are subject to vandalism or corrosion or contacts with flammable liquids or gases. These known switches are used typically as programming buttons for apparatuses for which, according to reference standards, it is necessary to use only casings that have a high degree of protection (for example IP69K) or are made of special materials, such as stainless steel and the like.

In particular, switches which are vandal-proof, corrosion-resistant or sealed against gases and/or liquids are known which are constituted by a box-like body, generally made of steel, and use rings made of special materials to ensure the seal between the movable parts, such as the pushbutton associated with the switch.

Other solutions use a flexible membrane as a part of the external body, and the residual flexibility of this membrane is used to activate a sensitive mechanical switch located proximate to the internal surface; in this case, the membrane must be made of special material and must in any case be heat-sealed to the rest of the container.

These known types of device are not free from drawbacks, which include the fact that they have movable parts, which therefore require special refinements in order to ensure their tightness against the liquids and/or gases that are present in the operating environment.

Further, these known types of switch have relatively short lifespans, since the movable parts and the sealing means are subjected to rapid wear in hostile operating conditions.

Moreover, the resulting switch has high manufacturing costs, which arise substantially from the sealing means, which have to be made of special materials, and from the general complexity of the construction.

Other solutions use capacitive or optical principles, but these solutions cannot work through a metal wall and are relatively immune to wet dirt.

U.S. Pat. No. 5,648,719 discloses a switch that provides a cavity formed in a box-like body, in which a metallic tool for activating the switch can be inserted. In particular, such switch is formed by a magnet and by a magnetically sensitive element, between which the cavity is interposed. The insertion of the metallic tool inside the cavity modifies the magnetic flux between the magnet and the magnetically sensitive element, activating the switch.

In general, adjusting the apparatus by means of rotary movements transmitted to a rotary switch or potentiometer is avoided, since the sealing means to be used would be too expensive and bulky: therefore, complex activation sequences and preferably self-learning procedures are used.

WO/1997/027673 discloses methods for passing an analog data item to a sensor by turning a tool provided with a magnet, which is applied to a suitable blind seat provided on the wall of the sensor.

Such known switches and adjustment devices also have drawbacks. In particular, the cavity provided in the box-like body, which is needed to activate/deactivate the switch/adjustment device, has a large diameter and/or is relatively deep and therefore bulky; further, it is a place of accumulation of liquids and dirt, which in stationary conditions of use may cause accidental variations of the magnetic field between the magnet and the magnetically sensitive element, with consequent anomaly in the operation of the device.

Another drawback is that the dirt or liquids that can be accumulated in the cavity can lead to deterioration by corrosion, in certain work environments, of the walls of the cavity. Further, devices of this type do not allow to establish safety functions in order to limit effectively access to the adjustment functions only to authorized personnel.

### SUMMARY OF THE INVENTION

The aim of the present invention is to eliminate the above-mentioned drawbacks of the background art, by providing a switch for adjustment or switching that can be used in special environments and is highly reliable in operation, regardless of the environmental conditions in which it is placed.

Within this aim, an object of the invention is to provide a device that has a range of performance from the simplest to the most complex, is capable of protecting adequately access to reserved functions, and can make the adjustment operation more intuitive.

Another object of the invention is to provide apparatuses for special environments with a control/adjustment point that has high mechanical and chemical resistance and does not have surfaces of discontinuity or deep recesses.

Another object of the present invention is to provide a device that is simple, has a reduced number of components, is relatively easy to provide in practice, is safe in use and effective in operation, and has a relatively low cost.

This aim and these and other objects, which will become better apparent hereinafter, are achieved by the inductive switch for adjustment and switching according to the invention, which comprises an inductive component and a container in which the inductive component is accommodated proximate to a wall of the container, the inductive component being connected to an electronic evaluation circuit, which is adapted to detect variations of parameters of the inductive component caused by the approach of a metallic object to the wall. The evaluation circuit, or a control circuit connected thereto, comprises means for detecting and identifying a predefined sequence of approach and spacing of the metallic object with respect to said wall and for modifying its functional parameters according to said sequence, optionally generating an actuation signal that is dependent on said sequence to be sent to an apparatus connected to the evaluation circuit. The sequence can comprise one or more pairs of approach/spacing movements of the metallic object with respect to said wall.

### BRIEF DESCRIPTION OF THE DRAWINGS

Further characteristics and advantages of the present invention will become better apparent from the following detailed description of a preferred but not exclusive embodiment of a switch, illustrated by way of non-limiting example in the accompanying drawings, wherein:

FIG. 1 is an axial sectional view of a generic cylindrical sensor, illustrating the inductive programming switch according to the invention;

FIG. 2 is an exploded view of the device of FIG. 1;

FIG. 3 is a transverse sectional view of the inductive component of the device of FIG. 1;

FIG. 4 is a view of a first evaluation circuit connected to the inductive component of the device according to the invention;

FIG. 5 is a view of a second evaluation circuit connected to the inductive component of the device according to the invention;

FIG. 6 is a block diagram of a sensor that uses the programming device according to the invention;

FIG. 7 is a block diagram of the sensor of FIG. 6, using an electronic screwdriver to transmit magnetic pulses;

FIG. 8 is a diagram of the electronic screwdriver that can be used in FIG. 7.

### DESCRIPTION OF THE PREFERRED EMBODIMENTS

With reference to the figures, the reference numeral 1 generally designates an inductive programming switch according to a particular embodiment, which is preferably adapted to communicate with an electronic adjustment screwdriver that will be described hereinafter. The device 1 comprises a container 2, which accommodates an inductive component 3, which is isolated from the surrounding environment by means of the container 2 and optionally by means of at least one gas- or liquid-tight connection 4 between the container 2 and other elements of an apparatus with which the device 1 is associated. Depending on the applications, the apparatus can be optionally accommodated in the same container 2 as the inductive component 3 or be dissociated into two or more containers interconnected by means of cables, of which only one can contain the inductive component 3 and optionally part of the evaluation circuits.

The container 2 can be made of steel (for example AISI 316L) or plastics or other materials suitable for the particular environment in which the device 1 is placed.

The inductive component 3 comprises at least one coil 5, which is wound on or in a ferromagnetic core 6 which, in the preferred embodiment of the invention shown in the figures, is of the so-called “pot” type and is made of ferrite, normally used in inductive proximity sensors.

The embodiment with the coil 5 wound in a pot core allows to have excellent sensitivity, but the invention yields good results also with unshielded SMT cores of the commercial type, normally used for switching power supplies.

The inductive component 3 is arranged proximate to a wall 7 of the container that has a reduced thickness (comprised for example between 0.3 and 0.7 mm) or is otherwise adapted to avoid shielding completely the electromagnetic field generated by the coil 5.

The wall 7 can comprise, on the outer surface, a suitable indicator 8 of the optimum position of the inductive component 3, arranged preferably at the axis of the coil 5 and of the ferromagnetic core 6.

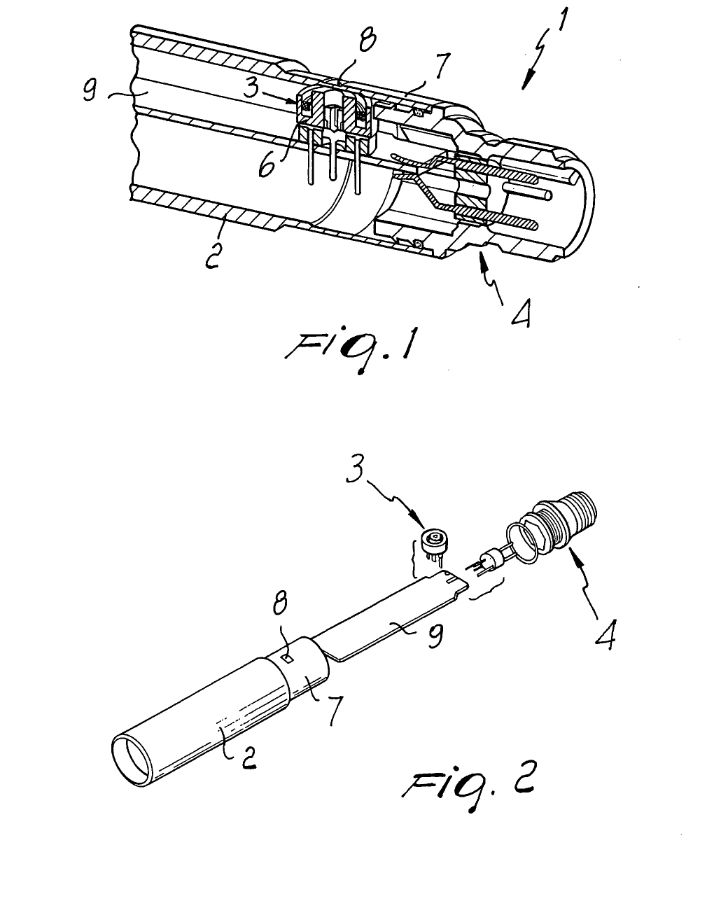

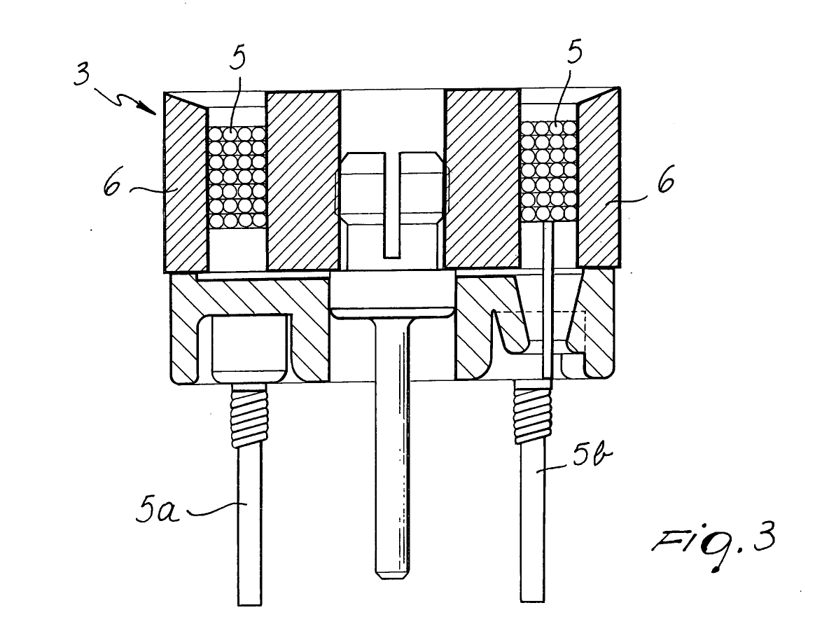

The indicator 8 applied to the outer surface can be only visual or also tactile, for example a label, a colored dot, a groove or a recess for a flathead or crosshead screwdriver. In FIGS. 1 and 2, the indicator 8 is a groove which is 0.2 mm deep and allows to detect easily the shank of a steel screwdriver 16, 100 having a diameter of 3 mm that is rested on the groove and to position easily said shank in the point of maximum sensitivity. The limited depth of the groove, in combination with the inductive nature of the system, in practice prevent performance degradations caused by any accumulation of dirt in the region of maximum sensitivity.

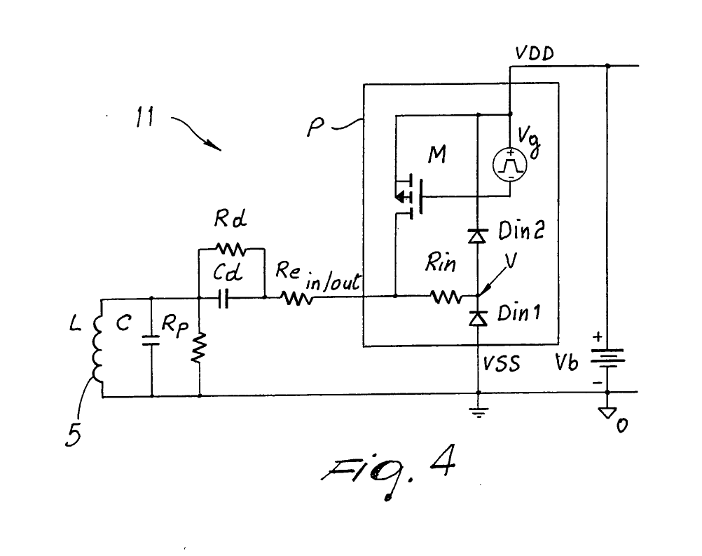

The container 2 further comprises an electronic board 9, which is fixed inside the container and to which the inductive component 3 is connected electrically by means of terminals 5a and 5b of the coil 5. The board 9 is adapted to support, so as to keep it close to the thin wall 7 of the container, the inductive component 3, which in the particular embodiment shown in FIG. 3 is fixed to the board 9 by soldering the terminals 5a and 5b.

The electronic board 9 can comprise an interface and evaluation circuit 11 for the signal that arrives from the coil 5 of the inductive component. Said circuit can be arranged alternately in a remote position, for example inside the apparatus that can be activated by means of the switch 1, and in this case the electronic board 9 can comprise only the necessary tracks for connection to the evaluation circuit.

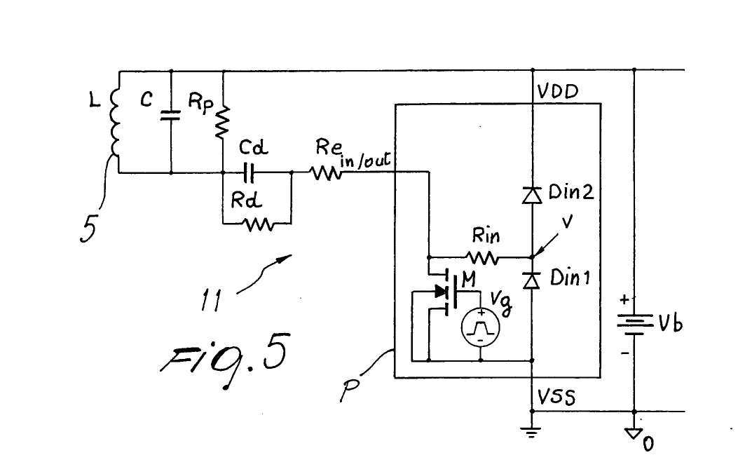

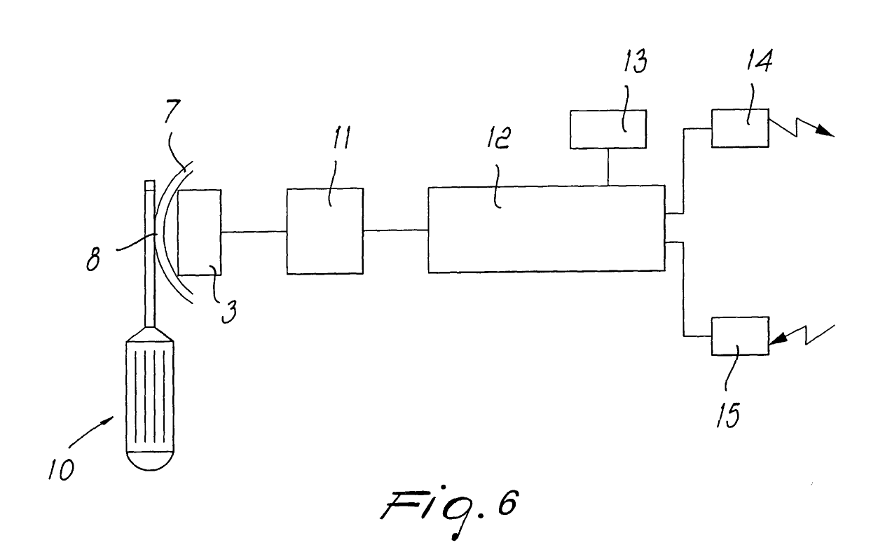

FIGS. 4 and 5, to which reference is made equally hereinafter, illustrate two possible evaluation circuits installed on the electronic board 9, respectively in the pMOS and nMOS versions, designated by the same reference numeral 11.

In the circuit 11, the coil 5 of the inductive component 3 is coupled to a capacitor so as to form an LC resonator, which optionally contains a leak resistor Rp. The frequency of the resonator can be chosen relatively low, for example 75 kHz, so as to obtain a good transparency to the magnetic field of the steel container 2. The inductance of the coil 5 and the capacitance of a capacitor C can be chosen equal to 213 μH and 22 nF, respectively.

The LC resonator is coupled to the rest of the circuit by means of a suitable capacitor Cd, which together with a corresponding resistor Rd defines a time constant Cd*Rd that affects the damping time constant of the resonator. The application of a short excitation pulse therefore generates a complex signal formed by the sum of a damped oscillation generated by the LC resonator, which can decay completely in less than 1 ms, and of a voltage pulse with exponential decay, which is extinguished completely in a much longer time, which depends on the time constant Cd*Rd. In the example of FIGS. 4 and 5, the capacitor Cd has a capacitance of 33 nF, while the resistor Rd has the resistance of 330 kΩWith these values, the time constant Cd*Rd is relatively long with respect to the decay time of the damped oscillation generated by the LC resonator and it is possible to use Cd and Rd as instant polarizing circuit in order to maintain the oscillation for a short time at an average value of 0.5 Vb, where Vb is the polarization voltage of the circuits of FIGS. 4 and 5.

The evaluation circuit 11 further comprises a microcontroller P (or an ASIC), which is connected to the LC resonator by means of the elements Cd and Rd. The microcontroller P comprises an internal switching element M, which in FIGS. 4 and 5 is respectively a p-type MOSFET and an n-type MOSFET, and is adapted to generate excitation pulses for the LC resonator and to analyze the damped oscillation of the signal generated by the resonator. In particular, the microcontroller P comprises an input gate for analyzing the complex signal that is present in a node V indicated in FIGS. 4 and 5, which is described hereinafter.

The internal switching element M, optionally provided with an input protection resistor Rin, is driven by a voltage pulse source Vg and is adapted to switch the current, for example 25 mA, needed to obtain the desired initial oscillation amplitude and the desired average oscillation value.

Optionally, if the internal switching element M is not a current source, an additional resistor Re that is external to the microcontroller P is connected between the element M and the unit Cd−Rd, so as to define the excitation energy.

The microcontroller P can further comprise an input protection network, which comprises the resistor Rin and the protection diodes Din1 and Din2, which however can have an oscillation limiting effect if the voltage of the generated signal exceeds the supply voltage values Vdd or Vss (with Vdd−Vss=Vb=5V in the particular example shown). Therefore, in order to avoid a reduction in the sensitivity of the device 1, it is possible to use the dipole Cd−Rd as a polarization unit.

In order to control the initial amplitude of the oscillation, the microcontroller P can control the excitation energy by adjusting the duration of the excitation pulse, preferably to a maximum duration that corresponds to the duration of half of the oscillation period, thus allowing to use the simple and low-cost resources of the microcontroller P.

The period of repetition of the excitation pulse can be chosen in various manners. In a first manner, the period of repetition can be so long, for example 50 ms, as to allow practically the complete exhaustion of the damped oscillation and of the exponential transient determined by Cd*Rd. In a second manner, the repetition period can be relatively short, for example 1 ms, so as to allow the complete exhaustion of the damped oscillation only, which typically takes approximately 500 μs to exhaust itself. In a third manner, the period of repetition can be very short, for example 50 μs, i.e., such as to regenerate the oscillation immediately after performing the read, but before the oscillation itself decays below a certain value.

In order to analyze the signal of the resonator, the microcontroller P can comprise a comparator connected to the node V between the two diodes of FIGS. 4 and 5 in order to square initially the sinusoidal signal or, if the level of the oscillation of the particular application has a sufficient amplitude, the microcontroller P can utilize the logic levels of an input gate thereof.

The simple circuit described is highly versatile and can be used for all the intended functions.

In order to verify the presence of a metallic shank proximate the sensitive point 8, it is sufficient to detect a higher oscillation damping rate by sampling for example the peak level of a certain pseudoperiod n of the oscillation, for example the fifth one.

In order to verify the presence of an external programming device arranged proximate to the sensitive point, it is sufficient to observe whether there is a signal, which the external programming device is adapted to produce, with a delay (for example 500 μs) with respect to the signal that is self-generated in the switch 1, i.e., when said self-generated pulse has already been exhausted and at a time that is distant from a subsequent excitation.

Optionally, the microcontroller P or a control circuit 12 connected to, or integrated in, the evaluation circuit 11 can be programmed to react to given sequences of approach and spacing of the activation tool 10 with respect to the sensitive point 8, changing their functional parameters in a manner that corresponds to a preset prescription.

Further, the microcontroller P or the control circuit 12 can adjust the sensitivity of the evaluation circuit every time the circuit is switched on, so as to counterbalance any variations in sensitivity induced by mechanical settling or variations of the boundary conditions of the sensor. This adjustment can be performed also during normal operation of the evaluation circuit, in order to avoid sporadic activations of the switch or long-term drifts.

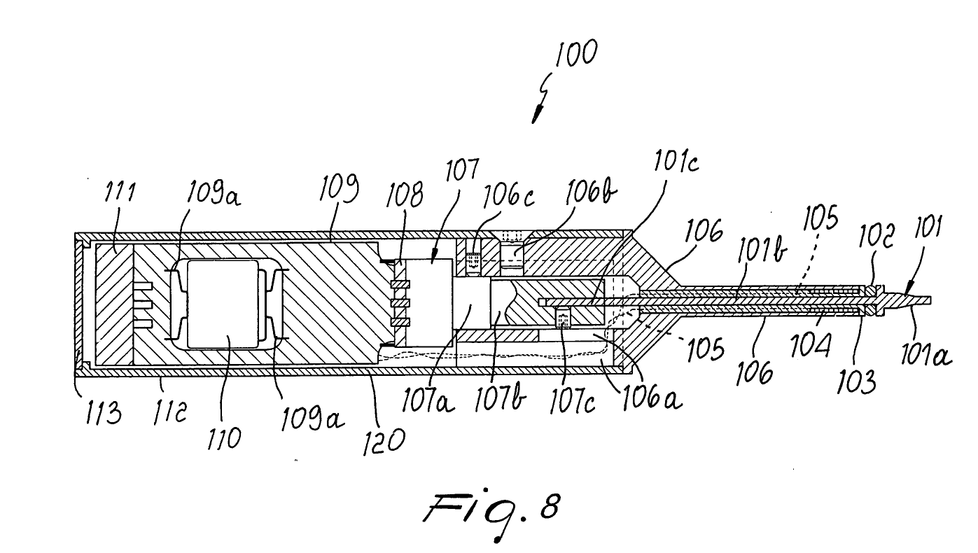

Advantageously, the programming device according to the invention can be associated with an electronic activator, for example an electronic screwdriver 16, as shown in FIG. 7, which comprises a handle 17 and a shank 18 and is provided with a source of electromagnetic pulses that is connected to the shank in order to transmit said pulses to the inductive component 3 of the programming device.

In particular, the handle 17 of the electronic screwdriver 16 can move axially and/or rotate with respect to the shank 18 and is connected to the electromagnetic pulse source (not shown in the figures), so that the axial and/or rotary motion of the handle 17 with respect to the shank 18 activates the pulse source.

Therefore, the control circuit 12 can be programmed to detect and interpret the movement of the handle 17 with respect to the shank 18, optionally making a distinction between movement along the axis of the shank 18 and rotation. For example, the control circuit can interpret the first movement as an actuation of a pushbutton and the second movement as a rotation of a trimmer. The control circuit 12, which optionally can be incorporated in the microcontroller P, is therefore programmed to generate an activation signal that depends on the specific magnetic pulses generated with the electronic screwdriver 16 and received by means of the inductive component 3.

The control circuit 12 or the microcontroller P therefore is suitably programmed to detect, in addition or as an alternative to the function for detecting approach or spacing, an electromagnetic signal that is external to the device 1, in order to determine that said signal is a signal for adjusting or programming the device and to perform an operation that depends on said signal, for example on its oscillation frequency or on the average or maximum amplitude of the train of damped oscillations that compose it. The operation can be for example a switching of said device, a programming of said evaluation circuit, or an adjustment of at least one parameter of said device.

In order to allow mutual movement between the handle 17 and the shank 18, the indicator 8 that is present on the wall 7 of the container preferably consists of an incision that is complementary to the tip of the electronic screwdriver and is deep enough to prevent the rotation of the shank 18 with respect to the wall 7 of the container.

The handle of the electronic screwdriver 16 can further contain a circuit that is also capable of receiving any magnetic pulses generated by the apparatus in which the programming device 1 according to the invention is installed, so as to establish bidirectional communications capable of transferring complex information.

Further, the control circuit 12 can measure the time for which the screwdriver 10 or 16 remains in the position in contact with the wall 7 and work on the basis of this measurement: for example, the circuit 12 can interpret a brief contact as a simple activation command and a prolonged contact as a command to change the operating mode of the circuit 12, for example from the active mode to the learning mode.

Of course, in the control circuit 12 other functions can be implemented without difficulties by the person skilled in the art.

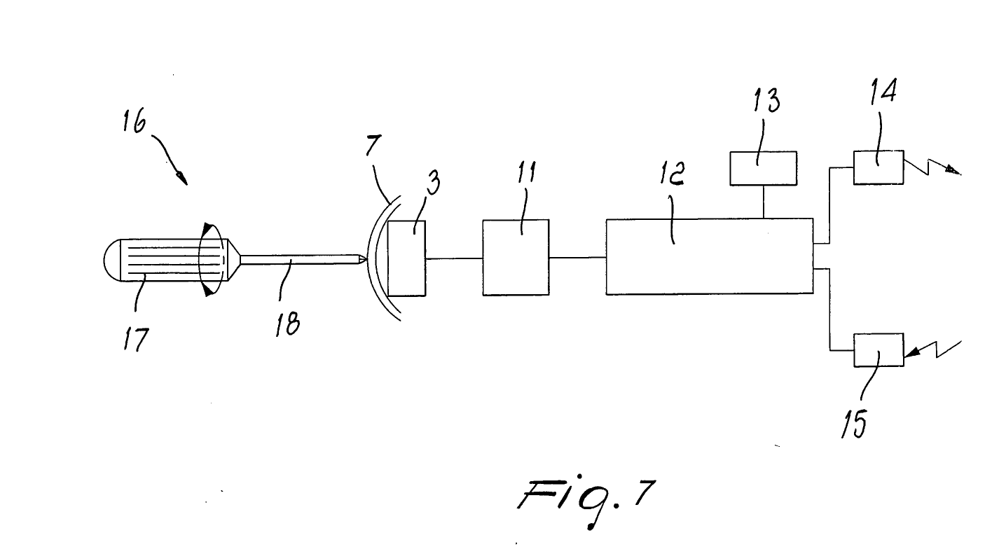

Optionally, as shown in FIGS. 6 and 7, the control circuit can be connected to an optical indicator 13 (display or LED), and to other electronic components, for example a sensitive device 15 or an actuator 14.

FIG. 8 illustrates in detail a possible electronic screwdriver 100, which can be used in the example of FIG. 7. The screwdriver 100 is constituted substantially by two parts, a shank 101 and a handle 120 that is coaxial to the shank, provided so that the shank 101 and the handle 120 can have mutual movements, for example a rotary movement and an axial movement.

The shank 101, made of ferromagnetic material, preferably soft iron, comprises an exposed tip 101a, which bears the shape that corresponds to the recess 8 provided on the wall of the apparatus to be controlled, and a thin internal shank 101b, which is surrounded by cylindrical structures 103 and 106, which have a guiding and protective function and are described hereinafter. The end part 101c of the shank that lies opposite the tip 101a is anchored to a sensor 107, which resides within the handle and is capable of detecting movements and/or mutual forces between the shank and the handle.

The sensor 107 is preferably an encoder and the shank 101 is coupled to a slider 107b of the sensor 107 by means of a grub screw 107c. The body 107a of the sensor 107 is fixed to the structure 106 by means of a grub screw 106c.

The sensor 107 is capable of providing in output pulses as a function of the angle and direction of rotation of the slider 107b and a signal that indicates the axial movement of the slider 107b.

The thin shank 101b of the screwdriver constitutes the core of a coil 104 and is adapted to gather the lines of force and facilitate mutual coupling with the coil 5.

Around the shank 101 there is a protective sheath 106, preferably made of stainless steel, which can be fixed to the enclosure 112 of the handle 120 by means of a screw 106b and encloses a second sheath 103 made of insulating material, which proximate to the tip 101a of the shank has a recess which, together with the internal surface of the first sheath 106, forms a seat for the coil 104.

The second sheath 103 is provided with axial grooves, not shown, which allow to accommodate wires 105 for connecting the coil 104 to an interface circuit that resides on a first printed circuit 109 inside the handle 120. Further seats 106a for the passage of the connecting wires 105 are provided in the first sheath 106.

Optionally, a ring 102 may be present between the tip 101a of the shank and the nearby end of the second sheath 103, said ring being adapted to ensure a seal toward the inside of the screwdriver, to adjust the rotational friction and to condition the axial compression force.

The electronic components dedicated to the functions of interface with the coil 104 and with the sensor 107 are installed on board the first printed circuit 109, and so are a processing unit, an interface with a display 111 and optionally other additional pushbuttons. On the circuit 109 there may also be a housing for a battery 110 and connecting clips 109a for the battery.

The display 111 and optionally some pushbuttons may be anchored to the end part of the printed circuit 109. Preferably, on the enclosure 112 of the handle 120 there is a transparent window 113, which make the display 111 visible and optionally there are holes or there is a flexible membrane to allow the actuation of any pushbuttons.

The sensor 107 may have, on the bottom, a second printed circuit 108, which is adapted to facilitate the connections of the terminals to the first printed circuit 109.

The processing and interface circuits of the electronic screwdriver 100 mounted on the first printed circuit 109 can repeat exactly the structure of the circuits of FIG. 4 or 5, with the difference that they further comprise a suitable input for the output terminals of the encoder 107.

The coil 104 of the screwdriver and the associated capacitor must resonate on the same frequency as the LC resonator of the switching device 1.

The operation of the present invention is as follows. The microcontroller P periodically sends an excitation pulse to the LC resonator 5, which generates a damped sinusoidal signal of definite amplitude and frequency. When the switch 1 must be activated, the user moves a metallic object, such as a screwdriver 10,16 or an electronic screwdriver 100, closer to the indicator 8 that is provided on the outer surface of the container 2. The approach of such a metallic object, particularly of a ferrous object, produces a reduction in the quality factor Q of the coil 5 and therefore in the amplitude of the oscillating signal of the LC resonator, which is conveniently detected by the gate of the microcontroller P or by the comparator contained therein. In a very specific subsequent interval, when the oscillation on the LC resonator of the switch 1 has damped completely, i.e., its amplitude has decreased below a predefined tolerance threshold, the microcontroller P checks whether pulses that originate from outside are received: if no pulse is detected, the microcontroller P presumes that a simple shank or metallic object has been moved closer and starts a procedure for accepting commands that is based on the approach mode, understood in terms of number and duration of approaches.

Optionally, depending on the applications, the microcontroller P or the control circuit 12 records a sequence of approach and spacing of the metallic object with respect to the indicator 8 and sends a corresponding activation signal to the apparatus once the sequence has ended.

If instead an electromagnetic signal generated externally is detected, the microcontroller P or the control circuit 12 assumes that an electronic screwdriver 100 such as the one shown in FIG. 8 has been moved closer and begins a bidirectional communication procedure that allows to use calibration procedures or in any case procedures for exchanging data and programs.

In practice it has been found that the described invention achieves the intended aim and objects, since it allows a high degree of reliability independently of the particular environmental conditions or degradations of the container.

The switch and the compatible apparatus according to the invention further achieve the intended aim and objects with a structure that is simple and devoid of magnets, relatively easy to provide in practice, safe to use, effective in operation, and having a cost that is relatively low or in any case proportionate to the requirements.

The invention thus conceived is susceptible of numerous modifications and variations, all of which are within the scope of the appended claims.

All the details may further be replaced with other technically equivalent elements.

In practice, the materials used, as well as the contingent shapes and dimensions, may be any according to requirements without thereby abandoning the scope of the protection of the appended claims.

The disclosures in Italian Patent Application No. MO2007A000275 from which this application claims priority are incorporated herein by reference.

Where technical features mentioned in any claim are followed by reference signs, those reference signs have been included for the sole purpose of increasing the intelligibility of the claims and accordingly, such reference signs do not have any limiting effect on the interpretation of each element identified by way of example by such reference signs.

1-10. (canceled)

11. An inductive programming switch for applications in special environments, comprising an inductive component and a container in which said inductive component is accommodated proximate to a wall of the container, said inductive component being connected to an electronic evaluation circuit, which is adapted to detect variations of parameters of the inductive component caused by the approach of a metallic object to said wall, said evaluation circuit comprising means for detecting and identifying a predefined sequence of approach/spacing of the metallic object with respect to said wall and for modifying its functional parameters according to said sequence.

12. The device according to claim 11, wherein said wall of the container comprises a visual or tactile indicator of the position of the inductive component, said means for detecting and identifying the variations of parameters of the inductive component being sensitive to the approach of the metallic object to said indicator, said visual or tactile indicator being a label or a colored dot or an incision provided on the outer surface of said wall.

13. The device according to claim 12, wherein said inductive component is a coil wound on or in a ferromagnetic core, and said indicator is arranged at the axis of said coil.

14. The device according to claim 11, wherein said circuit comprises a capacitor that is connected to said inductive element so as to form an LC resonator, said evaluation circuit comprising means for generating excitation pulses and for analyzing the oscillating response of said resonator to said pulses, said parameters variations being variations in the amplitude of oscillating signals generated by said resonator in response to said pulses.

15. The device according to claim 14, wherein said evaluation circuit comprises means for varying the duration of said pulses, so as to vary the amplitude of the oscillation of said oscillating signals.

16. The device according to claim 14, wherein said evaluation circuit comprises means for detecting an electromagnetic signal that is external to the switch, means for determining that said external signal is a signal for adjusting or programming the switch, and means for performing an operation that depends on said external signal, said operation being selected from the group that comprises a switching of said device, a programming of said evaluation circuit, an adjustment of at least one parameter of said switch.

17. The device according to claim 16, wherein said means for detecting the external electromagnetic signal are configured to detect said external signal when said oscillating signal generated by the LC resonator in response to the respective pulse is damped completely, i.e., its amplitude has dropped below a predefined tolerance threshold.

18. A unit for programming electronic apparatuses for use in special environments, comprising an inductive programming switch according to claim 11 and an electronic activator, said electronic activator comprising a shank and a corresponding handle that can move with respect to said shank, said handle containing a source of electromagnetic pulses that is associated with said shank and can be actuated according to movements of said handle with respect to the shank, so that said electromagnetic pulses can be transmitted to said inductive component through said shank when said shank is in contact with said wall of the container, the evaluation circuit of the switch being configured to modify its own functional parameters on the basis of the electromagnetic pulses generated with said movements of the handle.

19. The programming unit according to claim 18, wherein said movements comprise at least one movement in a direction that is coaxial to said shank and/or at least one movement of rotation about the axis of said shank.

20. The programming unit according to claim 18, wherein said shank is made of ferromagnetic material and comprises a coil that is wound around at least one portion thereof and is connected to said source of electromagnetic pulses and to a capacitor, so as to form an LC resonator, said shank being connected rigidly to an encoder that is sensitive to the rotation of said shank about its own axis and/or to the translational motion of said shank along its own axis, said encoder being connected in output to an adjustment input of said source of electromagnetic pulses so as to modify the duration and/or amplitude and/or phase of said pulses according to the output signal of said encoder.
